(19) United States
(12) Patent Application Publication
(10) Pub. No.: US 2026/0292550 A1
(43) Pub. Date: Sep. 24, 2026

(54) MEASUREMENT AND REPORTING OF METRICS FOR PERFORMANCE MONITORING

(71) Applicant: InterDigital Patent Holdings, Inc., Wilmington, DE (US)

(72) Inventors: Akshay Malhotra, San Jose, CA (US); J. Patrick Tooher, Montreal (CA); Yugeswar Deenoo Narayanan Thangaraj, Chalfont, PA (US); Mihaela Beluri, Jericho, NY (US); Mohamed Salah Ibrahim, Chesterbrook, PA (US); Ahmet Serdar Tan, London (GB); Anouar Yatribi, London (GB); Moon-il Lee, Melville, NY (US)

(73) Assignee: InterDigital Patent Holdings, Inc., Wilmington, DE (US)

(21) Appl. No.: 19/168,412

(22) PCT Filed: Apr. 2, 2024
(86) PCT No.: PCT/US2024/022679

§ 371 Date: Sep. 24, 2025

Related U.S. Application Data
(60) Provisional application No. 63/456,758, filed on Apr. 3, 2023.

(51) Int. Cl. H04W 24/08; H04B 7/06; H04W 24/10

(52) U.S. Cl. CPC H04W 24/08; H04B 7/0626; H04W 24/10

(57) ABSTRACT

Systems, methods, and instrumentalities are disclosed herein for measuring and reporting metrics for performance monitoring. A device may receive configuration information that indicates an input data type, a set of reference vectors, and a distance metric type. The device may receive a channel state information (CSI) reference signal (CSI-RS). The device may determine measured CSI based on a measurement associated with the CSI-RS. The device may generate compressed CSI based on the measured CSI and the input data type. The device may calculate, based on the distance metric type, a distance metric associated with the measured CSI and a reference vector in the set of reference vectors. The device may send a report to a network node. The report may indicate the compressed CSI and the distance metric associated with the measured CSI and the reference vector in the set of reference vectors.

### CROSS-REFERENCE TO RELATED APPLICATIONS

This application claims the benefit of U.S. Provisional Patent Application No. 63/456,758, filed Apr. 3, 2023, the contents of which are hereby incorporated by reference herein.

### BACKGROUND

Mobile communications using wireless communication continue to evolve. A fifth generation may be referred to as 5G. A previous (legacy) generation of mobile communication may be, for example, fourth generation (4G) long term evolution (LTE).

### SUMMARY

Systems, methods, devices, and instrumentalities are described herein related to measurement and reporting of metrics for performance monitoring.

A device (e.g., a wireless transmit/receive unit (WTRU)) may be configured to receive configuration information that indicates an input data type, a set of reference vectors, and a distance metric. The device may receive a channel state information (CSI) reference signal (CSI-RS). The device may determine measured CSI based on a measurement associated with the CSI-RS. The device may generate compressed CSI based on the measured CSI and the input data type. The device may calculate, based on the distance metric, a distance associated with the measured CSI and a reference vector in the set of reference vectors. The device may send a report to a network node. The report may indicate the compressed CSI and the distance associated with the measured CSI and the reference vector in the set of reference vectors.

The device may calculate the distance associated with the measured CSI and the reference vector in the set of reference vectors by calculating respective distances between the measured CSI and each reference vector in the set of reference vectors.

The distance metric may be a normalized mean square error (NMSE). The device may calculate the distance associated with the measured CSI and the reference vector in the set of reference vectors by calculating the NMSE of the measured CSI and the reference vector in the set of reference vectors.

The distance metric may be a cosine similarity. The device may calculate the distance associated with the measured CSI and the reference vector in the set of reference vectors by calculating the cosine similarity of the measured CSI and the reference vector in the set of reference vectors.

Calculating the distance associated with the measured CSI and the reference vector in the set of reference vectors may involve calculating respective distances between the measured CSI and each reference vector in the set of reference vectors, and wherein the report further indicates a smallest distance of the respective distances or a largest distance of the respective distances.

The distance metric may be a function that maps input tensors to a scalar value. The distance associated with the measured CSI and the reference vector in the set of reference vectors may be the scalar value.

The reference vector is associated with a first domain, the distance metric may be associated with a second domain. The device may transform the reference vector from the first domain to the second domain. The input data type may be full channel matrix or eigenvector.

### BRIEF DESCRIPTION OF THE DRAWINGS

FIG. 1A is a system diagram illustrating an example communications system in which one or more disclosed embodiments may be implemented.

FIG. 1B is a system diagram illustrating an example wireless transmit/receive unit (WTRU) that may be used within the communications system illustrated in FIG. 1A according to an embodiment.

FIG. 1C is a system diagram illustrating an example radio access network (RAN) and an example core network (CN) that may be used within the communications system illustrated in FIG. 1A according to an embodiment.

FIG. 1D is a system diagram illustrating a further example RAN and a further example CN that may be used within the communications system illustrated in FIG. 1A according to an embodiment.

FIG. 2 illustrates an example of a two-sided artificial intelligence/machine learning (AI/ML)-based channel state information (CSI) compression framework.

FIG. 3 illustrates an example set of reference vectors, measured CSI, and distance metrics.

FIG. 4 illustrates an example of determining the set of reference vectors.

FIG. 5 illustrates an example of determining distances, sub-band groups, and quantization level.

### DETAILED DESCRIPTION

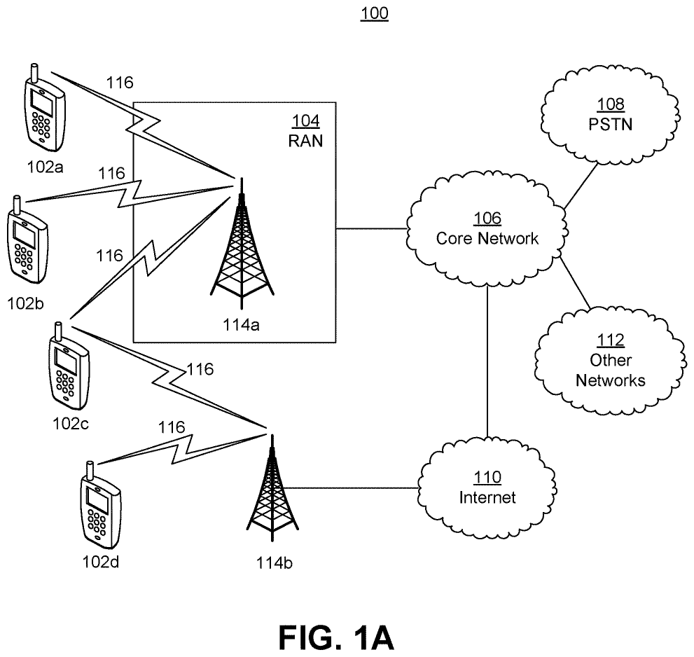

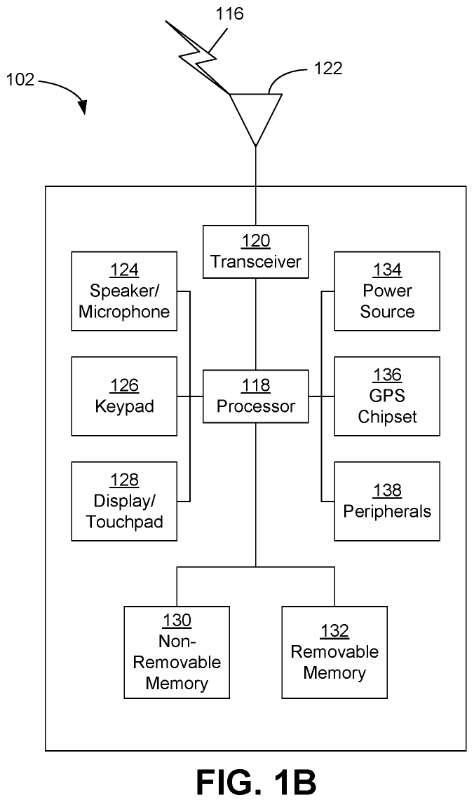

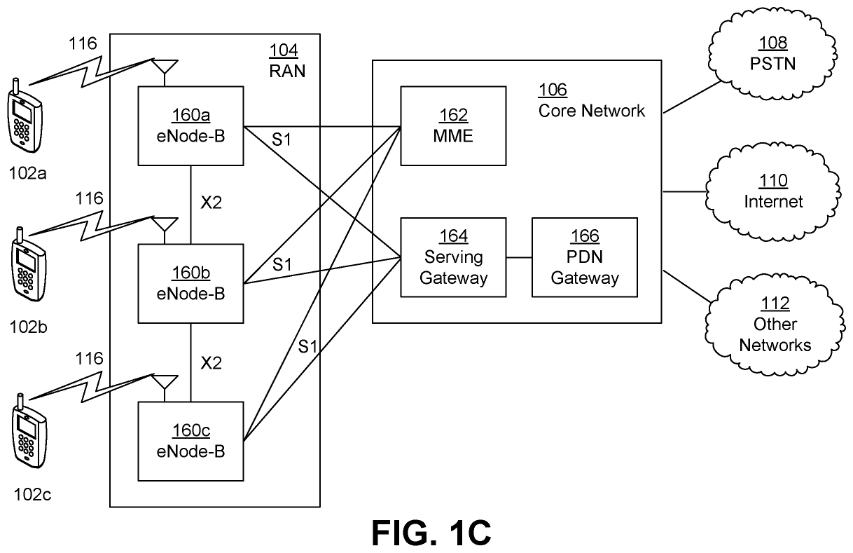

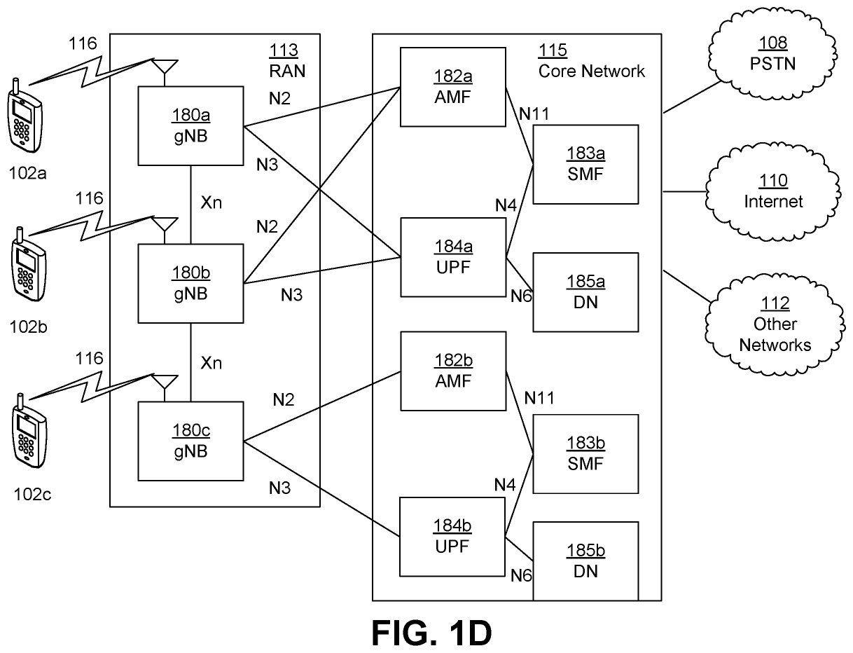

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., a eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WiMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth© module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (CoMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Systems may use two-sided models (e.g., AI/ML models, for example, for CSI feedback). In such systems, the features described herein may be implemented by a WTRU to determine and report a CSI compression performance. The features described herein may enable life cycle monitoring (LCM) (e.g., monitoring of WTRU-side models, for example, machine learning (ML) models).

Feature(s) associated with model monitoring are provided herein.

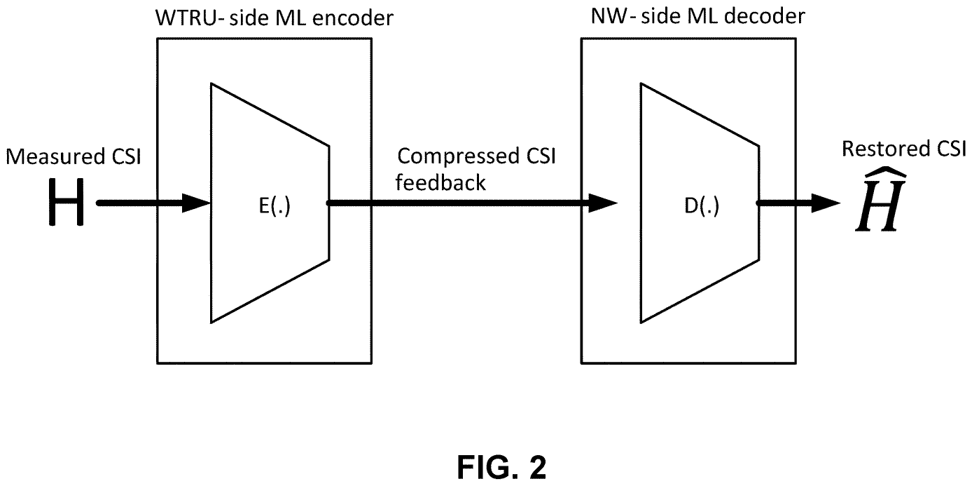

The AI/ML framework for CSI compression may include a two-sided model. In the two-sided model, CSI compression may be performed at the WTRU-side. The compressed CSI may be fed back to the network (NW) and decompressed (e.g., restored) at the NW-side. The WTRU-side processing for CSI compression may include an ML encoder (e.g., possibly preceded by a pre-processing stage). The NW-side processing may include an ML decoder (e.g., possibly followed by a post-processing stage, for example, if pre-processing is employed at the WTRU). The ML encoder and a corresponding ML decoder (e.g., that are operating in conjunction) may be referred to as an autoencoder (AE). FIG. 2 illustrates a high-level block diagram of two-sided AI/ML-based CSI compression framework.

The ML encoder and ML decoder part of the AE may be trained (e.g., either separately or jointly) using a training dataset. Training of the ML models may be performed offline (e.g., prior to deploying the models at the nodes (WTRUs and/or gNB)). During regular operation (e.g., at inference time), the performance of the compression (e.g., ML encoder) may degrade. Such degradation may happen, for example, if the distribution of the actual data does not match the distribution of the training dataset (which may be referred to as an out-of-distribution operation). The WTRU or network may detect when the performance of the CSI compression (and recovery) degrades. Appropriate mitigation mechanisms may be used (e.g., following detection). For example, mitigation may include a model update, on-line training, or fallback to legacy reporting.

Monitoring the WTRU-side model may help the WTRU or network detect and mitigate performance degradation (e.g., the CSI compression performance degradation).

Machine learning-based approaches (e.g., AE-based approaches) may reduce the CSI feedback overhead. However, upon deploying the ML models, the performance of the AI/ML-based CSI compression may degrade (e.g., if the distribution (statistics) of the actual propagation channel is different from the distribution of the dataset used for ML model training). ML model monitoring may be used to detect if the performance of the CSI compression degrades (e.g., such that appropriate mitigation measures may be applied).

The WTRU may have a copy of the ML decoder used by the NW. The WTRU may use the copy to determine the compression and reconstruction performance for ML model monitoring. The WTRU may use the ML decoder to reconstruct the CSI (e.g., based on the compressed CSI which is reported back to the NW), and compare the reconstructed CSI to the CSI measured by the WTRU.

However, the availability of ML decoders at the WTRU-side may not be possible. Support may be needed for multiple sizes (e.g., due to different gNB Tx antenna port configurations, or support of variable BW size). This may excessively increase the WTRU complexity (and may increase power consumption, since the WTRU may need to run the ML decoder solely for monitoring the performance of the ML encoder).

Feature(s) described herein may relate to lower-complexity techniques for the WTRU to determine the compression performance for ML encoder performance monitoring.

Feature(s) associated with measuring distances between the estimated CSI and a set of reference vectors (e.g., to enable determination of the compression performance) are provided herein.

Feature(s) associated with the WTRU determining and reporting (e.g., to the NW) distances (e.g., the best distances) to accurately determine the compression performance are provided herein.

Feature(s) associated with the WTRU determining and reporting how many distances are needed for compression performance determination are provided herein.

Feature(s) associated with the WTRU determining a set of reference vectors for distance measurements are provided herein.

Given an allocated report size, the WTRU may determine (e.g., jointly determine) the distance reporting parameters (e.g., such as quantization of the distances, averaging) and a number of distances to report.

Feature(s) associated with utilizing a set of reference vectors (R₁, R₂, . . . , R_{K}_{ₘₐₓ}) to detect any mismatch between the reconstructed CSI (at the gNB) and the actual CSI measured at the WTRU are provided herein.

For example, at the WTRU-side, a first distance (or some other metric) may be measured between the actual CSI Hⱼ measured at the WTRU and the set of reference vectors. At the NW-side, a second distance may be measured between the CSI [symbol] reconstructed at the NW and a set of reference vectors (e.g., the same set of reference vectors). If the two distances are found to be similar (e.g., Dist(Hⱼ, Rᵢ)≈Dist [symbol] , then Hⱼ≈ [symbol] and the reconstruction of the compressed CSI at the gNB side may be acceptable (e.g., good). Otherwise, the AE-based reconstruction may be unacceptable (e.g., poor) and mitigation strategies (e.g., a change of encoder-decoder pair or re-training) may be employed.

A reference vector or basis vector may refer to a vector or tensor available at both the WTRU and the gNB/network. A reference vector or basis vector may serve as a reference. For example, a distance or metric or quantity may be evaluated based on a comparison with the reference vector or basis vector. The i-th reference vector may be indicated as Rᵢ.

A set of reference vectors or a set of basis vectors may refer to the common set of multiple reference vectors, matrices, scalar values, or tensors available at both the WTRU and gNB/network. The set of reference vectors or set of basis vectors may be indicated as {R₁, R₂, . . . , Rᵢ, . . . , R_{K}_{ₘₐₓ}} if the reference is represented in matrix form, and as {r₁, r₂, . . . , rᵢ, . . . , rₖ_{ₘₐₓ}} if the reference is represented in vector form.

The distance metric may be a function that maps input tensors to a scalar value. In this case, the distance associated with the measured CSI and the reference vector in the set of reference vectors may be the scalar value. For example, the distance metric (e.g., the distance dist(Hⱼ, Rᵢ)) may refer to any function that maps a pair of vectors or tensors to a scalar. Such a function may be referred to as a distance or a metric, but may not obey the rules associated with (e.g., required to be) a distance or a metric. The terms distance, distance metric, or metric may be used interchangeably herein.

The terms raw channel, full channel (FC), full H, and full channel response matrix may be used interchangeably therein.

Feature(s) described herein may lower the WTRU complexity (e.g., because such feature(s) may not involve replicas of the AI/ML decoder being available at the WTRU).

Distance measurement(s) may involve minimal computation. The detection overhead (e.g., overall computation overhead for detection) at the WTRU and gNB may be low.

Feature(s) described herein may introduce minimal additional transmission overhead. Feature(s) described herein may utilize sending statistical measurements and quantized values to keep the transmission overhead low.

Feature(s) associated with detection performance are provided herein. Under the correct distance metric (e.g., for projections) and an optimal set of reference vectors, the WTRU may be able (e.g., guaranteed) to detect degradation (e.g., any degradation) in the compression performance up to a (e.g., any) defined precision. As the number of evaluated distances (e.g., with different reference vectors) increases, the detection performance may increase.

A WTRU may be configured to perform distance measurements (e.g., to support performance determination by the NW-side). The configuration may include a distance metric to be used, dist(.,.). The metric to be utilized for evaluation may be a function (e.g., any function) that maps a pair of input tensors (e.g., Hⱼ, Rᵢ) to a scalar real value. The function may not obey the rules/properties required for a function to qualify as a ‘metric’ or ‘distance’ (e.g., like triangle inequality and symmetricity). The choice of the metric may depend on the application domain and/or the type of data. Depending on the application, the objectives may be different (e.g., the objective(s) may include low reconstruction error, high alignment or cosine similarity, high perceptual quality, etc.). A function suited for the application and the objective(s) may be utilized.

For the CSI feedback application, if the reconstruction quality is gauged in terms of mean squared error, then distances like L2-norm of the error, mean squared error (MSE)), or normalized mean squared error (NMSE) may be relevant. Other norms of the reconstruction error may be used (e.g., L1-norm or Lp-norm, where p corresponds to any real value). If the reconstruction error vector is given by E, then the Lp-norm may be defined as:

$${\vert E \vert}_{p} = \sqrt[p]{{\sum }_{i} {\vert {E}_{i} \vert}^{p}}$$

For the CSI feedback use case, if the reconstruction quality is gauged in terms of cosine similarity between the eigenvectors of the actual and reconstructed CSI, a generalized cosine similarity or squared generalized cosine similarity (SGCS) may be used as the distance function.

Projection may be used as the function (e.g., for reconstruction or compression). The projection may capture the inner product between the (e.g., two) input values.

For a video or imaging application, perceptual quality metrics (e.g., structural similarity) may be used.

If the network identifies the optimal distance metric for the application at hand, the network may configure the WTRU with the metric. The potential options for the metrics maybe listed as a codebook. The network may indicate an index associated with the metric to be used (e.g., by the WTRU). Depending on the metric, additional configurable parameters may be defined. For example (e.g., in the case of a weighted MSE), the weights associated with each dimension may be configured (e.g., explicitly configured).

The configuration may include a reference set domain.

The reference set domain may indicate the domain of the data used to evaluate the performance of the two-sided model. For example, the domain of the data may be (e.g., directly) the tensor (e.g., for the CSI or channel matrix for the CSI compression use case). The domain of the data may be any derived quantity of the tensor (e.g., the eigenvectors of the tensor, for example, for the eigenvectors of the CSI). Full channel (FC) or Eigenvectors (EV) may be used for CSI compression, or another (e.g., any other) quantity that the can be derived from the CSI tensor may be used.

The configuration may include dimensionality reduction across sub-bands.

The CSI tensor Hⱼ may have a dimensionality of N_{c}×N_{R}×N_{T}, where N_{c} represents the number of sub-carriers, N_{R} represents the number of receive antennas, and N_{T} represents the number of transmit antennas. For evaluating the distance, the reference vectors Rᵢ may have the same dimensionality of N_{c}×N_{R}×N_{T} and a (e.g., single) distance may be evaluated per CSI. Given the high dimensionality of the data (and to evaluate more meaningful distances), an Rᵢ with a smaller dimensionality (e.g., N_{R}×N_{T}) may be used. In such a case, multiple distances may be evaluated (e.g., one for each of the sub-carriers, for example, N_{c} distances). Smaller dimensionality may be used by ignoring a different dimension (e.g., N_{c}×N_{T} or N_{T}) or by reducing the size of each of the dimensions of Rᵢ,

$$( e . g . , \frac{{N}_{c}}{2} \times \frac{{N}_{R}}{2} \times \frac{{N}_{T}}{2} ) .$$

Using a reduced dimensionality of Rᵢ, may result in multiple distances. For example, if Rᵢ has a dimensionality of N_{R}×N_{T}, N_{c} different distances may be evaluated and transmitted. To reduce the number of distances to be transmitted, the network may configure WTRU with different strategies specifically configured for reducing the number of distances.

Neighboring distances that have a similar value may be combined. In this case, if there are N_{c} distances corresponding to the N_{c} sub-carriers, the distances for some sub-carriers may be combined to have sub-band distances. The size and grouping of these sub-bands may be different from the one used for CSI reporting. The size and grouping of these sub-bands may be configured by the network (e.g., during the configuration stage).

To further reduce the values to be reported, multiple strategies may be employed. For example the mean and/or variance of the distances across the sub-bands may be evaluated. A moment (e.g., any other moment beyond mean, variance) may be utilized. Weighted version of the moments (e.g., weighted mean, weighted variance) may be utilized (e.g., because moments are statistical quantities and do not preserve the position information). A function (e.g., any function) that takes a multidimensional vector and outputs a scalar quantity may be utilized for this reduction.

Given a set of potential options for dimensionality reduction functions (e.g., mean/variance/weighted mean/weighted variance/max, etc.) the network may signal (e.g., explicitly signal) to the WTRU which function to use.

The configuration may include a reference set.

The reference vectors used for the distance evaluation may be the same at the network and WTRU. One or more reference vectors may be defined (e.g., to ensure accurate detection). The maximum (e.g., maximum required) number of reference vectors may depend on the dimensionality of the data and the variability of the data that will be encountered. For the CSI compression use case, the higher the variability in the Hⱼ, the greater the number of reference vectors. The reference set may use orthogonal/orthonormal reference vectors (e.g., because such reference vectors may capture the most variability with the fewest vectors). The reference vectors may not be orthogonal.

A set of reference vectors may be a large set of CSI tensors, Hⱼ(e.g., with a dimensionality of N_{R}×N_{T}), with the set having T different CSI tensors. These CSI tensors may be linearized as N_{R}N_{T}×1. The set of left EVs of the N_{R}N_{T}×T data matrix (e.g., where N_{R}N_{T}<T) may be used as a set of reference vectors.

The network may configure the WTRU with a set of reference vectors {R₁, R₂, . . . , Rᵢ, . . . , R_{K}_{ₘₐₓ}} (e.g., because the same set of reference vectors may be utilized for distance evaluation at both the WTRU and the network). The choice of reference vectors may depend on the data encountered by the gNB. The gNB (e.g., each gNB) may choose a different set of reference vectors.

The gNB/network may (e.g., choose to) configure the WTRU with a set of reference vectors. The reference vectors may be ordered or un-ordered. The ordered set may relay information to the WTRU such as, for example, which reference vectors are of higher importance, and the corresponding distances that may be prioritized.

Feature(s) associated with reference vector-based NW-side model performance evaluation are provided herein.

A set of reference vectors (R₁, R₂, . . . , R_{K}_{ₘₐₓ}) (or a plurality of sets) may be used to perform NW-size evaluation of the performance of a two-sided model.

At the WTRU-side, a first distance (or some other metric) may be measured between the actual measurement at the WTRU (e.g., CSI Hⱼ) and the set of reference vectors. Given the configurations of the distance metric (dist(.,.)), the set of reference vectors {R₁, R₂, . . . , Rᵢ, . . . , R_{K}_{ₘₐₓ}} and the mode of operation (FC or EV or etc.), the WTRU may evaluate the distance associated with the input data.

For the CSI use case, the data may be the CSI tensor Hⱼ with a dimensionality of N_{c}×N_{R}×N_{T}, and the reference vectors may have a dimensionality of N_{R}×N_{T}. The selected distance metric may be L2-norm and the mode of operation may be FC. In this case, N_{c} distances may be evaluated (e.g., one for each of the sub-carriers). In examples, N_{c} may refer to the number of sub-bands (e.g., in frequency domain) for which the channel response is measured. A distance (e.g., each of the distances) may be evaluated (for subcarrier/sub-band index nc) as:

$$dist ( {H}_{{j}_{nc}} , {R}_{i} ) = {\vert {H}_{{j}_{nc}} - {R}_{i} \vert}_{2}$$

The evaluated N_{c} distances may be combined based on the dimensionality reduction procedure configured by the WTRU. For example (e.g., if a mean-based dimensionality reduction scheme is defined), the mean of all the N_{c} distances may be computed and utilized for indicating the distance.

At the NW-side, a second distance, between the measurement reconstructed at the NW (e.g., CSI Ĥⱼ) and the same set of reference vectors, may be measured.

The same parameters and procedures may be repeated for distance evaluation on the network-side. Instead of the actual CSI measured by the WTRU, the network/gNB may use the reconstructed measurement (e.g., estimated/predicted CSI, [symbol] ) to evaluate the distances to the same set (sets) of reference vectors.

If the two distances are found to be similar (e.g., Dist(Hⱼ, Rᵢ)≈Dist( [symbol] , Rᵢ)), then Hⱼ≈ [symbol] and the reconstruction of the compressed CSI at the gNB side may be acceptable (e.g., good). Otherwise, the AE-based reconstruction may be unacceptable (e.g., poor). In this case, mitigation strategies (e.g., a change of encoder-decoder pair or re-training) may be employed.

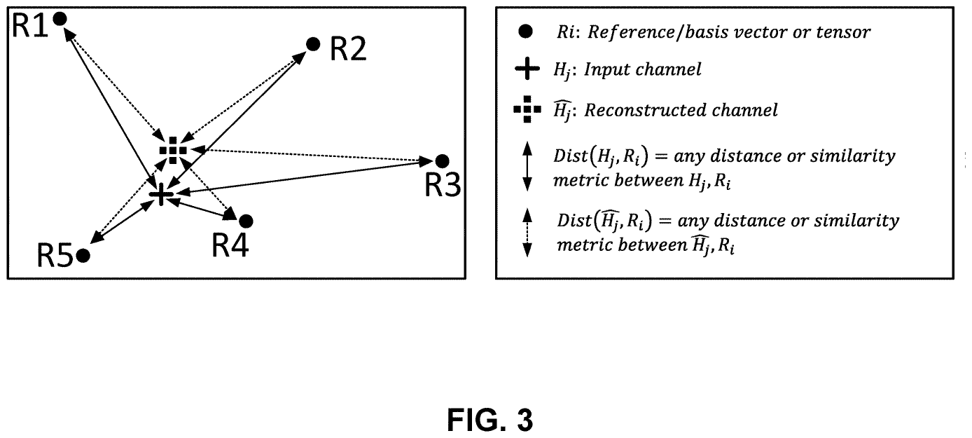

FIG. 3 illustrates an example set of reference vectors, measured CSI, and distance metrics.

The WTRU may report the distance metrics and selected reference vectors.

Example types of validation metrics are provided herein.

A WTRU may report information to enable life cycle management, verification, or validation of an AI/ML model. The WTRU may report the outcome of an AI/ML model, or of a transmission block. The WTRU may report validation metrics to enable a gNB to determine or validate the performance of at least one of: an AI/ML model, an AI/ML encoder, an AI/ML decoder, a transmission block, a reception block, and/or the like. The validation metrics reported by the WTRU may include a measured channel. For example, a WTRU may report a channel measurement obtained from at least one received RS. The measured channel may include the total channel measurement, or a set of eigenvalues associated with the channel measurements.

The validation metrics reported by the WTRU may include a compressed channel. For example, a WTRU may report a compressed channel measurement associated with (e.g., obtained from) measured channel measurement.

The validation metrics reported by the WTRU may include a reference vector. For example, the WTRU may report one or more reference vectors (e.g., determined based on features described herein). A reference vector report may include an index for a reference vector (e.g., for each of the reported reference vectors). The association between an index and a reference vector may be pre-configured or determined by the WTRU. A reference vector report may include parameters associated with the reference vector. For example, parameters associated with the reference vector may include the reference vector (e.g., the reference vector itself), or a compressed version of the reference vector.

The validation metrics reported by the WTRU may include a distance metric. For example, a WTRU may report at least one distance metric. The distance metric may be determined based on at least one of: a measured channel, a compressed channel, a reference vector, a measurement, or a configuration.

The validation metrics reported by the WTRU may include a number of reference vectors or distances. For example, a WTRU may report a number of reference vectors or distances (e.g., that the WTRU may determine for a measured channel or a compressed channel).

The validation metrics reported by the WTRU may include a confirmation of a reception of a distance metric. For example, a WTRU may receive one or more distance metrics from a node (e.g., a gNB). The WTRU may acknowledge reception of the distance metric. In an example, a WTRU may compare a received distance metric to a WTRU-calculated distance metric. The WTRU may report a differential value between the received and calculated distance metrics.

The validation metrics reported by the WTRU may include a request for a new set of reference vectors.

The validation metrics reported by the WTRU may include a request to train an AI/ML model. For example, a request to train an AI/ML model may include a model ID. The validation metrics reported by the WTRU may include an AI/ML model ID. The validation metrics reported by the WTRU may include an AI/ML encoder ID. The validation metrics reported by the WTRU may include a transmission block ID.

Feature(s) associated with reporting a resource used to report validation metrics are provided herein.

A WTRU may report validation metric(s).

The WTRU may report validation metric(s) using a feedback resource configured for, and used for, reporting CSI. For example, a WTRU may report a validation metric as part of a feedback report. In an example, the WTRU may report a set of reference vectors and/or a set of distance metrics (e.g., distance metrics associated with the set of reference vectors) as part of a feedback report that includes one or more compressed measurements. For example the feedback reporting resource may be configured to be periodic.

The WTRU may report validation metrics using a feedback resource configured for reporting validation metrics. For example, a WTRU may have dedicated reporting resources to report validation metrics. The WTRU may be configured with or may indicate a relationship between a first and second reporting resource. A validation metric may be reported in a first reporting resource and a compressed measurement may be reported in a second reporting resource. For example, the feedback report resource may be configured to be periodic.

The WTRU may report validation metrics using dynamically or aperiodically granted reporting resource(s). For example, a WTRU may be dynamically or aperiodically granted reporting resources to report validation metrics. In an example, a WTRU may request for dynamically granted reporting resources to transmit validation metrics.

The WTRU may report validation metrics using semi-persistent feedback resource(s). For example a WTRU may be triggered to use a semi-persistent resource to feedback validation metrics. The trigger to use a semi-persistent resource may include at least one of: an indication from the gNB, a determination that a measurement is above or below a threshold, an AI/ML model performance degradation, QoS degradation, and/or ACK-NACK performance degradation.

If a WTRU reports a subset of validation metrics in a resource that does not include the associated measurement or associated other validation metrics, the WTRU may be configured with a relationship between reporting resources (e.g., different reporting resources). The relationship between reporting resources may depend on the validation metric type reported in a reporting resource. For example, a WTRU may be configured with a first reporting resource that may include a set of reference vectors. The WTRU may determine (e.g., and report) one or more distance metrics in a reporting resource as a function of previously reported reference vectors (e.g., of the most recently reported set of reference vectors). The WTRU may determine (e.g., and report) one or more distance metrics in a reporting resource as a function of previously acknowledged reference vectors (e.g., where the acknowledgement comes from another node such as the gNB). A reporting resource with one or more distance metrics may be associated with at least one reporting resource with one or more measurements or compressed measurements. The relationship between the resource that includes the measurements and the resource that includes the distance metric may be configured.

A validation metric report may be assigned or configured with a priority level. The WTRU may determine whether to report a validation metric based on (e.g., as a function of) at least one of: the validation metric report priority, the priority of other reports to be reported in the resource, and/or the payload of the feedback resource. The validation metric priority may be determined by at least one of: priority of associated data, priority of the associated feedback report (e.g., measurement), priority of the function to be validated, and/or value of a validation metric. The validation metric priority may be determined based on (e.g., as a function of) the value of the validation metric, for example, the validation metric priority may be set based on determining that a distance metric is greater than a threshold. In an example, a WTRU may compare a WTRU-determined distance metric to a gNB-determined distance metric. If the difference is greater than or less than a threshold, the WTRU may increase or decrease the priority of a validation metric feedback report.

Feature(s) associated with triggers and maintaining distances are provided herein.

A WTRU may be configured to report validation metrics periodically, aperiodically, or semi-persistently. For example, a WTRU may be configured to report validation metrics in the same resource as an associated feedback report. In another example, a WTRU may be configured with periodic resources to report validation metrics. The periodic resources may be associated with periodic resources used to report associated feedback reports.

The WTRU may be triggered to determine or maintain a validation metric, or to report or start reporting a validation metric. For example, the WTRU may be triggered by a measurement value. For example, a WTRU may perform a measurement on an RS (e.g., RSRP, RSSI, RSRQ, CO, RI, CQI, PMI, LI, SINR, doppler shift, doppler spread, average delay, delay spread, AoA, AoD, etc.). Based on the value being above or below a threshold, the WTRU may be triggered to determine, maintain, report, and/or start reporting a validation metric. In an example, the WTRU may determine the value of a validation metric (e.g., the value of one or more distance metric associated with one or more reference vectors). The WTRU may be triggered to determine, maintain, report, and/or start reporting a validation metric based on the validation metric being above or below a threshold. The WTRU may be triggered to determine, maintain, report, and/or start reporting based on the change of a validation metric. For example, if a validation metric changes by more than a threshold value compared to a previously measured or reported validation metric, the WTRU may be triggered to report the validation metric (and possibly the previous validation metric).

The WTRU may be triggered based on the outcome of an associated function. For example, a WTRU may be triggered to determine, maintain, report, and/or start reporting a validation metric based on at least one of: feedback report timing, beam failure detection, radio link failure, unlicensed channel access outcome (e.g., successful LBT or unsuccessful LBT), ACK/NACK transmission, SRS transmission, uplink control information (UCI) transmission, RS reception, PDCCH or PDSCH reception, paging message reception, SIB reception, RACH procedure, AI/ML model change, determination of one or more NACKs, reception of a retransmission grant, etc.

The WTRU may be triggered based on timing. For example, a WTRU may be triggered to determine, maintain, report, and/or start reporting a validation metric based on the absolute time, slot, or frame. In another example, a WTRU may be triggered to determine, maintain, report, and/or start reporting a validation metric based on a relative time, slot, or frame (e.g., relative to another event). The relative timing may be relative to events such as at least one of: feedback report timing, beam failure detection, radio link failure, unlicensed channel access outcome (e.g., successful LBT or unsuccessful LBT), ACK/NACK transmission, SRS transmission, UCI transmission, RS reception, PDCCH or PDSCH reception, paging message reception, SIB reception, RACH procedure, AI/ML model change. In another example, a WTRU may be triggered to determine, maintain, report, and/or start reporting a validation metric based on the time since a previous report of a validation metric. In another example, a WTRU may be triggered to determine, maintain, report, and/or start reporting a validation metric based on a period of time since a triggering condition was first met.

The WTRU may be triggered based on transmission performance. For example, a WTRU may be triggered to determine, maintain, report, and/or start reporting a validation metric based on the performance of an UL or DL or SL transmission. For example, the WTRU may be triggered based on the ACK/NACK performance (e.g., the trigger may depend on whether the percentage of NACKs in a time period is greater or less than a threshold).

The WTRU may be triggered based on QoS or instantaneous QoS.

The WTRU may be triggered by reception of a request from another node. For example, a WTRU may be triggered to determine, maintain, report, and/or start reporting a validation metric based on reception of an indication from the gNB. The indication may be at least one of: PDCCH indication, DCI indication, MAC CE indication, RRC (re)configuration, DL RS reception, SL RS reception, RAR message, etc.

The WTRU may be triggered by a change in scenario. For example, a WTRU may be triggered to determine, maintain, report, and/or start reporting a validation metric based on a change in scenario (e.g., such as going from being at a fixed position to being mobile). A WTRU may be triggered by at least one of the following: a change in mobility, a change in LOS/NLOS, a change in measurements greater than threshold (e.g., RSRP, RSSI, RSRQ, CO, RI, CQI, PMI, LI, SINR, doppler shift, doppler spread, average delay, delay spread, AoA, AoD, etc.), a change in beams (e.g., Rx beam, Tx beam, or Tx/Rx beam pair), a cell change, a TRP change, a QoS change (e.g., new traffic types associated with new requirements), etc. Such changes in scenario may be associated with a change in AI/ML model.

The WTRU may be triggered based on a previous trigger. For example, a WTRU may be triggered to determine, maintain, report, and/or start reporting a validation metric based on whether the WTRU was previously triggered to measure, maintain, report, and/or start reporting a validation metric, and/or the timing of such a previous trigger, and/or the type of previous trigger.

The WTRU may be triggered based on reception of a validation metric report from another node. For example, a WTRU may be triggered to determine, maintain, report, and/or start reporting a validation metric based on receiving a validation metric from the gNB. For example, the WTRU may receive one or more distance metrics calculated by a gNB. The WTRU may be triggered to report a validation metric based on at least one of: receiving the gNB-calculated validation metric, the value of the gNB-calculated validation metric, the difference between a gNB-calculated validation metric and an associated WTRU-calculated validation metric, etc.

The WTRU may be triggered based on a counter or timer. For example, a WTRU may be configured with a trigger counter and/or a timer. If the number of triggering events is greater than a configurable value, possibly during a configured amount of time, a WTRU may be triggered to determine, maintain, report, and/or start reporting a validation metric. The triggering events may be any of the triggers described herein.

A WTRU may be triggered to stop reporting a validation metric using any of the triggers described herein.

A WTRU may determine the contents of a validation metric report based on configuration or based on any of the triggers described herein.

Feature(s) associated with WTRU measurement and reporting of distances/metrics for performance monitoring are provided herein.

Example configuration aspects are provided herein. Example reference set(s) configurations are provided herein.

A WTRU may receive configuration information. The configuration information may indicates a set of reference vectors, an input data type, and a distance metric type. For example, the WTRU may be configured with a plurality of reference sets (e.g., I reference sets) in support of monitoring the performance (e.g., compression) of two-sided AI/ML models. The reference set may be defined as Rᵢ={R₁, R₂, . . . , Rᵢ, . . . , R_{K}_{ₘₐₓ}}, for i={1, . . . , I}, and Kₘₐₓ may represent the maximum number of candidates associated with a specific reference set. Kₘₐₓ may change from one reference set to another (e.g., based on an NW configuration). A candidate (e.g., each candidate) in the reference set may represent a scalar (e.g., eigenvalue), a vector (e.g., principal eigenvector), a matrix (e.g., a wideband channel matrix or multiple eigenvectors in wideband), or a 3D array or tensor (e.g., multiple channel matrices or eigenvectors across multiple sub-bands). A WTRU may be configured with or indicated a particular reference set (e.g., chosen by the NW) to perform and report measurements (e.g., distance) for AI/ML model monitoring.

A reference set (e.g., each of the reference sets) may be characterized and indicated with one or more parameters. For example, a reference set (e.g., each of the reference sets) may be characterized and indicated with a ReferenceSet-ID. The ReferenceSetID may represent the reference set logical identity. The reference set logical identity may indicate (e.g., to the WTRU) a reference set to use for distance measurement.

A reference set (e.g., each of the reference sets) may be characterized and indicated with a ReferenceSet-MaxSize (Kₘₐₓ). The ReferenceSet-MaxSize (Kₘₐₓ) may indicate the maximum number of candidates (e.g., vectors, matrices, tensors) that the WTRU may use from the configured reference set.

A reference set (e.g., each of the reference sets) may be characterized and indicated with a ReferenceSet-NrofdistanceToreport (k). The ReferenceSet-NrofdistanceToreport (k) may indicate the number of k distances to report out of the configured Kₘₐₓ candidates included in the configured reference set. ReferenceSet-NrofdistanceToreport (k) may be signaled if (e.g., only if) k is less than Kₘₐₓ. Otherwise, if ReferenceSet-NrofdistanceToreport (k) is not signaled, the WTRU may assume that k is equal to Kₘₐₓ.

A reference set (e.g., each of the reference sets) may be characterized and indicated with a ReferenceSet-Kₘₐₓ-mode. ReferenceSet-Kₘₐₓ-mode may be a binary parameter indicating whether the configured Kₘₐₓ candidates are ordered (e.g., sorted). For example, if ReferenceSet-Kₘₐₓ-mode is set to ‘1,’ the configured set may be ordered. In this case, the WTRU may assume that the k distance measurement are to be done on the first k candidates in the configured reference set. Otherwise (e.g., if ReferenceSet-Kₘₐₓ-mode is set to ‘0’), the WTRU may assume that the configured set is not ordered. In this case, the WTRU may receive an indication of the indices of the candidates to be used for distance measurement.

A reference set (e.g., each of the reference sets) may be characterized and indicated with a ReferenceSet-k-locations. ReferenceSet-k-locations may indicate the indices of the k out of Kₘₐₓ candidates to be used to compute and report the distance measurement. This parameter may be configured if (e.g., only if) the reference set candidates are not ordered (e.g., the parameter ReferenceSet-Kₘₐₓ-mode is set to ‘0’).

A reference set (e.g., each of the reference sets) may be characterized and indicated with a ReferenceSet-Domain. ReferenceSet-Domain may indicate the configured reference set, {R₁, R₂, . . . , Rᵢ, . . . , R_{K}_{ₘₐₓ}} domain (e.g., eigenvector (EV) or full channel). The WTRU may use the indicated domain to perform and report the measured distances. The WTRU may use the reference set domain to pre-process prior to the distance measurement (e.g., the reference set domain may be full channel, but the WTRU may receive an indication to measure the distances in the EV domain).

A reference set (e.g., each of the reference sets) may be characterized and indicated with a ReferenceSet-DistanceDomain. ReferenceSet-DistanceDomain may indicate the distance domain in which to perform the distance measurement. For example, ReferenceSet-DistanceDomain may indicate that the distance domain is eigenvalue, eigenvector, or full channel.

A reference set (e.g., each of the reference sets) may be characterized and indicated with a ReferenceSet-DistanceMetricType. ReferenceSet-DistanceMetricType may indicate the metric in which to measure the distance. For example, ReferenceSet-DistanceMetricType may include (but not be limited to) normalized mean squared error (NMSE), (generalized) cosine similarity, matrix norm, projection, etc.

Feature(s) associated with a WTRU measuring distances are provided herein.

A WTRU may be configured to perform and report k metrics (e.g., distance metrics/measurements) based on one or more of the following.

For example, a WTRU may be configured to perform and report k metrics (e.g., distance metrics/measurements) based on a configured reference set format (e.g., scalar, vector, matrix, tensor). A WTRU may be configured to perform and report k metrics (e.g., distance metrics/measurements) based on configured distance metric types (e.g., NMSE, cosine similarity, projection). A WTRU may be configured to perform and report k metrics (e.g., distance metrics/measurements) based on a configured input data type (e.g., reference set domain, for example, full channel, eigenvector, eigenvalue).

A WTRU may be configured to perform and report k metrics (e.g., distance metrics/measurements) based on a configured distance domain (e.g., full channel, eigenvector, eigenvalue).

The WTRU may use the configured information for measuring and reporting the k distances. The configured reference set domain may be different from the configured distance domain. In this case, the WTRU may pre-process/transform the reference set domain to the distance domain (e.g., before computing the distances) based on the indicated metric. If the reference vector is associated with a first domain and the distance metric type is associated with a second domain, the WTRU may transform the reference vector from the first domain to the second domain. For example, a WTRU may be indicated or configured with a reference set in the full channel domain while the configured distance domain is eigenvector or eigenvalue. The WTRU may derive the eigenvectors or eigenvalues associated with the reference set to measure the distance in the indicated or configured distance domain.

To perform the k distance measurements, the WTRU may (e.g., may first) estimate the full channel matrices

$${\{ {H}_{n} ∈ {C}^{{N}_{r} x {N}_{t}} \}}_{n = 1}^{{N}_{c}}$$

across sub-bands (e.g., across all configured N_{c} sub-bands). The WTRU may pre-process the estimated channel across sub-bands (e.g., all sub-bands) for proper distance computations.

The WTRU may perform a distance measurement based on reference sets with tensor candidates.

The WTRU may be configured with a reference set {R₁, R₂, . . . , Rᵢ, . . . , R_{K}_{ₘₐₓ}}, where each candidate in the reference set is in a three-dimensional tensor format (e.g., {Rᵢ∈C^{N}^{ᵣ}^{×N}^{ₜ}^{×N}^{_{c}}}. A candidate (e.g., each candidate) may represent the full channel domain or the eigenvectors associated with the wideband full channel. The WTRU may measure (e.g., directly measure) the k distances based on the configured distance metric. For example, in the case of NMSE, the WTRU may compute the k distances as follows:

$${d}_{i} = \frac{1}{{N}_{c}} {\sum }_{n = 1}^{{N}_{c}} \frac{{‖ {H}_{n} - {R}_{in} ‖}_{F}^{2}}{{‖ {H}_{n} ‖}_{F}^{2}}$$

where Rᵢₙ represents the n-th sub-band associated with the i-th reference sample, ∥·∥_{F} denotes the Frobenius norm of a matrix, and i=1, . . . , k.

The WTRU may be configured to report the minimum and/or maximum distance across sub-bands (e.g., across all sub-bands). For example, the WTRU may calculate respective distance metrics between the measured CSI and each reference vector in the set of reference vectors, and report a smallest distance metric of the respective distance metrics or a largest distance metric of the respective distance metrics. In this case, the k distances may be computed as follows:

$${d}_{i} = {min}_{n} \frac{{‖ {H}_{n} - {R}_{in} ‖}_{F}^{2}}{{‖ {H}_{n} ‖}_{F}^{2}}$$

The WTRU may perform a distance measurement based on reference sets with matrix candidates.

The WTRU may be configured with a reference set {R₁, R₂, . . . , Rᵢ, . . . , R_{K}_{ₘₐₓ}}, where a candidate (e.g., each candidate) in the reference set is in a matrix format (e.g., {Rᵢ∈C^{N}^{ᵣ}^{×N}^{ₜ}}. A candidate (e.g., each candidate) may represent the wideband full channel domain or the eigenvectors associated with the wideband full channel. The WTRU may pre-process/transform the estimated channel to be consistent with reference set domain for appropriate distance measurements. For example, the WTRU may average out the estimated channels across sub-bands (e.g., across all sub-bands) to compute the wideband channel H̅∈C^{N}^{ᵣ}^{×N}^{ₜ}, as follows:

$$\overline{H} = \frac{1}{{N}_{c}} {\sum }_{n = 1}^{{N}_{c}} {H}_{n}$$

The WTRU may measure the k distances between H and the k indicated candidates from the configured reference set based on the configured distance metric and configured distance domain. For example, if the distance domain is indicated as eigenvectors, the WTRU may (e.g., further) pre-process/transform the reference set candidates and the measured/estimated channel to the distance domain before computing the distances. The k distances may be computed based on the indicated distance metric type. The distance metric type may be NMSE. The WTRU may calculate the NMSE of (e.g., between) the measured CSI and a (e.g., each) reference vector in the set of reference vectors. For example, if the indicated distance metric type is the NMSE, the WTRU may compute the k distances as follows:

$${d}_{i} = \frac{{‖ \overline{H} - {R}_{i} ‖}_{F}^{2}}{{‖ \overline{H} ‖}_{F}^{2}}$$

where ∥·∥_{F} denotes the Frobenius norm, and i=1, . . . , k.

The WTRU may receive an indication of the distance domain as the eigenvector. In this case, the WTRU may (e.g., first) derive the eigenvectors V̅, associated with the wideband channel matrix H̅. The WTRU may compute the distance in the EV domain. The distance metric type may be cosine similarity. The WTRU may calculate the cosine similarity of (e.g., between) the measured CSI and a (e.g., each) reference vector in the set of reference vectors. For example, if the distance metric is indicated as the cosine similarity, the WTRU may compute the k distances as:

$${d}_{i} = {\sum }_{j = 1}^{J} \frac{1}{J} {\vert {r}_{ij}^{*} {v}_{j} \vert}^{2}$$

where J denotes the number of layers, * denotes the conjugate transposition, νⱼ∈C^{N}^{ₜ} is the j-th eigenvector of the channel matrix H̅, and rᵢⱼ is the j-th reference vector associated with the reference matrix Rᵢ.

The WTRU may perform a distance measurement based on reference sets with vector candidates.

The WTRU may be configured with a reference set {r₁, r₂, . . . , rᵢ, . . . , rₖ_{ₘₐₓ}}, where a candidate (e.g., each candidate) in the reference set is in a vector format (e.g., {rᵢ∈C^{N}^{ₜ}}. A candidate (e.g., each candidate) may represent the principal eigenvector associated with the wideband channel or may be vectors selected from the discrete Fourier transform (DFT) matrix. The WTRU may pre-process/transform the estimated channel to be consistent with reference set domain for appropriate distance measurements. For example, the WTRU may average out the estimated channels across sub-bands (e.g., across all sub-bands) to compute the wideband channel H̅∈C^{N}^{ᵣ}^{×N}^{ₜ}. The WTRU may derive the principal eigenvector ν∈C^{N}^{ₜ}. The WTRU may compute the k distances between the measured eigenvector and the indicated k references from the set {r₁, r₂, . . . , rᵢ, . . . , rₖ_{ₘₐₓ}} based on the indicated distance metric (e.g., NMSE, cosine similarity).

The WTRU may perform monitoring based on eigenvalues measurements.

The WTRU may receive an indication instructing the WTRU to measure and report one or more eigenvalues associated with the estimated wideband matrix, denoted as {α₁, α₂, . . . , αₖ}. The multiple eigenvalues may correspond to the number of layers supported by the WTRU.

The WTRU may be configured to compute and report an (e.g., one) eigenvalue for a configured sub-band (e.g., each configured sub-band). The computed eigenvalue may correspond to the maximum eigenvalue for a given sub-band channel matrix or the average across all eigenvalues associated with a given sub-band channel matrix Hₙ, for n=1, . . . , N_{c}. To monitor the AI/ML performance, the NW may compute a set of eigenvalues of the decompressed channel

$${\{ \overline{H} \}}_{n = 1}^{{N}_{c}} ,$$

denoted as {\hat{α}₁, \hat{α}₂, . . . , \hat{α}ₖ}. The NW may monitor the performance based on a function of the reported eigenvalues associated with the encoder input and the derived eigenvalues based on the decoder output. For example, if the reported eigenvalues are close to the derived eigenvalues by the NW, the NW may conclude that the reconstruction (e.g., at the decoder output) is acceptable.

The WTRU may report the measured distances.

The WTRU may report the measured k distances to be used for two-sided AI/ML model monitoring. The WTRU may be configured to indicate the measured k distances along with the output of the AI/ML encoder (e.g., compressed CSI). The WTRU may report the k distances in a MAC control element. The WTRU may report the k distances on a PUCCH resource. The WTRU may report k distance in PUSCH resource.

The WTRU may be configured to report the k distance periodically, semi-persistently, or aperiodically. The aperiodic reporting may occur based on one or more triggers. The WTRU may be configured to transmit the k distances based on one or more preconfigured events. For example, the WTRU may be configured to transmit the k distances if the performance of PDSCH changes (e.g., BLER exceeding a configured threshold). In another example, the WTRU may be configured to transmit the k distances if input data drift is identified by the WTRU. The WTRU may be configured to transmit the k distances if the AI/ML model is switched.

Feature(s) associated with WTRU measurement and reporting of distances and/or metrics for performance monitoring are provided herein.

A WTRU may measure and report k distances between measured CSI and k reference vectors. This may enable NW-side to determine compression performance (e.g., for life-cycle management).

A WTRU in a system using two-sided models (e.g., AI/ML models) for compression (e.g., for CSI feedback) may be configured to perform distance measurements (e.g., in support of compression performance determination by the NW-side). The configuration may include one or more of the following: a distance metric type to be used (e.g., NMSE, cosine similarity, matrix norm, projection, etc.); a set of reference vectors for distance measurement (e.g., with a total Kₘₐₓ reference vectors in the set); an input data type (e.g., the full channel response matrix (full H) measured at the WTRU-side, or the eigenvectors (EV) of the channel response); and/or a number k of distances to be reported (e.g., where k is smaller or equal to the size of the reference set, Kₘₐₓ).

The WTRU may receive CSI-RS. The WTRU may determine measured CSI based on a measurement associated with the CSI-RS. The WTRU may generate compressed CSI from the measured CSI (e.g., based on the measured CSI and the configured input data type (full H or EV)). The WTRU may calculate Kₘₐₓ distance metrics between the measured CSI and a reference vector (e.g., each vector) in the configured set of reference vectors (e.g., based on the configured distance metric type). The WTRU may send a report to a network node. The report may indicate the compressed CSI and/or the determined k distance(s) between the measured CSI and the reference vector(s).

A device (e.g., a wireless transmit/receive unit (WTRU)) may be configured to receive configuration information. The configuration information may indicate an input data type, a set of reference vectors, and a distance metric type. The device may receive a channel state information (CSI) reference signal (CSI-RS). The device may determine measured CSI based on a measurement associated with the CSI-RS. The device may generate compressed CSI based on the measured CSI and the input data type. The device may calculate (e.g., based on the distance metric type) a distance metric associated with (e.g., a distance between) the measured CSI and a reference vector of the set of reference vectors. The device may send a report to a network node. The report may include the compressed CSI and the distance metric associated with the measured CSI and the reference vector of the set of reference vectors.

The input data type may be a full channel matrix or an eigenvector. The device being configured to calculate the distance metric associated with the measured CSI and the reference vector of the set of reference vector may involve the device being configured to calculate a distance metric between the measured CSI and each reference vector of the set of reference vectors.

A WTRU may determine the number of distances/metrics to report.

Example configuration aspects are provided herein.

A WTRU may receive (e.g., be configured to receive) CSI-RS for estimation of CSI. The WTRU may determine measured CSI based on a measurement associated with the CSI-RS. The WTRU may generate/calculate compressed CSI based on an input data type and the measured CSI. The input data type may include (but not be limited to) full channel, eigenvector, etc. The WTRU may be configured to report a distance metric with the channel (e.g., such that the errors in the reconstructed channel may be detected and/or mitigated). The WTRU may receive (e.g., from the gNB) configuration information (e.g., one or more configuration aspects) associated with determination of a number of distance metrics to report. For example, the configuration information may indicate the input data type, a set of reference vectors, a distance metric type, and an error threshold. The WTRU may be configured to feedback a distance metric (e.g., such that the number of distance metrics in the feedback satisfies a preconfigured criterion).

The WTRU may be configured with one or more reference vectors {R₁, R₂ . . . Rₙ} to use for distance metric feedback. The reference vectors may correspond to basis vectors for the overall channel space. The reference vectors may be predefined. The reference vectors may be cell-specific and/or configured in broadcast signaling. The reference vectors may be configured in RRC signaling. The reference vector configuration may be WTRU-specific. The reference vectors may correspond to the eigenvectors. The reference vectors may correspond to DFT vectors. The reference vectors may be a channel matrix, channel realization/sample, etc.

The WTRU may be configured to determine/derive a set of distance metric(s) (e.g., based on the configured distance metric type). The distance metric may refer to the distance between the measured channel at the WTRU and one or more reference vectors configured for the WTRU. The distance metric may be configured such that the quality of reconstruction may be inferred based on the distance relationship between the reference vectors and the measured channel on the WTRU and the reconstructed channel at the gNB. For example, the set of distance metrics may include a first distance metric associated with the measured CSI and a first reference vector in the set of reference vectors, and a second distance metric associated with the measured CSI and a second reference vector in the set of reference vectors, etc. For example, the relationship between the channel matrix H measured at the WTRU and the reconstructed channel Ĥ at the gNB may be expressed/inferred/derived/determined based on the distance(s) between H and {R₁, R₂ . . . Rₙ} compared to the distance(s) between Ĥ and {R₁, R₂ . . . Rₙ}. The distance metric may (e.g., explicitly or implicitly) indicate a performance metric associated with CSI compression. For example, the distance metric may serve as a proxy to measure the similarity between the two channels H and Ĥ.

The distance metric may be configured as the cosine similarity metric or variations thereof. For example, the WTRU may determine the set of distances by calculating the cosine similarity of the measured CSI and a first reference vector, and the cosine similarity of the measured CSI and a second reference vector. The distance metric may be the normalized mean squared error. For example, the WTRU may determine the set of distances by calculating the NMSE of the measured CSI and the first reference vector, and the NMSE of the measured CSI and the second reference vector. The distance metric may be Euclidian distance. The distance metric may be a projection of the channel matrix onto the reference vectors.

The WTRU may be preconfigured with one or more distance metric types. The WTRU may derive the type of distance metric based on the preconfigured rules. For example, the WTRU may determine the type of distance metric to use based on overhead/payload size of the feedback, number of reference vectors, sub-band size, error bound, type of input used for compression (e.g., full channel or eigenvector), etc. The WTRU may be configured with a percentage error threshold, Thrₑᵣᵣ. The WTRU may use the percentage error threshold to determine the number of distance metrics to include in the feedback. For example, the WTRU may determine a subset of the set of distance metrics (e.g., based on the error threshold). The set size of the subset may be indicative of a number of distance metrics in the subset. Different values of Thrₑᵣᵣ may be configured for the WTRU. The WTRU may select the threshold to use based on the type of distance metric, overhead/payload size of the feedback, input type used for compression, etc.

The WTRU may determine the number of distance metrics to report (e.g., the number of distance metrics in the subset of distance metrics).

The WTRU may be configured to determine the minimum number of distances k to feedback according to a preconfigured condition. For example, the WTRU may be configured to determine and report k distance(s) based on (e.g., as a function of) the configured error threshold. For example, the WTRU may calculate the distance between each of the configured reference vectors and the measured channel or a pre-processed version thereof (e.g., eigenvector).

The WTRU may determine the set of distance metrics by determining a smallest number of distances, from the set of distances, for which an energy amount associated with the distances is greater than a threshold percentage of a total energy amount. The threshold percentage may be equal to one hundred minus the error threshold (e.g., (100−Thrₑᵣᵣ)%). For example, the WTRU may determine the minimum number of distances k, such that the energy of the distances (e.g., projections) to the k reference vectors is larger than (100−Thrₑᵣᵣ)% of the total energy (e.g., such that the reported distances conserve at least (100−Thrₑᵣᵣ)% of the energy).

The WTRU may send a report to a network node. The report may indicate the compressed CSI and the number of distance metrics in the subset. For example, the WTRU may be configured to report a minimum/default number of distance metrics (e.g., kₘᵢₙ) and a maximum number of distance metrics (e.g., Kₘₐₓ). The WTRU may (e.g., dynamically) select the number of distance metrics k_{actual} based on one or more criteria described herein. For example, the WTRU may be configured to select a minimum number of distances (e.g., in addition to the number of default distances) that satisfies a preconfigured criterion. The report may further indicate the distance values associated with the distance metrics in the subset of distance metrics. The report may indicate indices associated with the reference vectors associated with the subset of distance metrics.

The WTRU may be configured with a set of default reference vectors. The distances of the default reference vectors may be included in the feedback report. The WTRU may be configured with a set of (e.g., optional) reference vectors. The distances of the optional reference vectors may be included in the feedback report (e.g., if the default reference vector distances does not meet the configured error threshold). The WTRU may be configured with a priority associated with a reference vector (e.g., associated with each of the reference vectors). The WTRU may be configured to include the distance metric (e.g., starting from highest priority reference vector to the lowest priority reference vector). The WTRU may be configured to determine the number of distance metrics to include in the report based on (e.g., as a function of) one or more of the following: quantization applied to distance metric, type of input (e.g., full channel or eigenvector), number of sub-bands, overhead/payload size configured for the feedback, etc.

The WTRU may determine a number of distance(s) to report based on the type and/or identity of the encoder and/or decoder configured for CSI compression. For example, the WTRU may be configured with a mapping between the encoder or decoder or encoder-decoder pair and a distance reporting configuration. The distance reporting configuration may include a number of distance(s) to report, a type of distance metric to use, a type of quantization to be applied, a set of reference vectors to use, etc. An encoder (or decoder or encoder-decoder pair) used for CSI compression, may (e.g., implicitly) correspond to a distance feedback configuration. For example, the WTRU may determine a change in distance feedback configuration if the WTRU detects a change in the encoder (or decoder or encoder-decoder pair).

The WTRU may report the distance measurements.

The WTRU may be configured to report one or more distance metrics/parameters associated with performance monitoring. As used herein, such reporting may be referred to as distance metric feedback, a distance metric report, etc. Such performance monitoring may be applicable for two-sided models. Such reporting may be periodic, semi-persistent, and/or event triggered.

The WTRU may be configured to report distance metric(s) multiplexed with CSI feedback. For example, the WTRU may transmit CSI feedback in one or more (e.g., two) parts. The first part may include compressed CSI feedback. The second part may include the distance metric(s). The WTRU may transmit the CSI feedback in a first UCI. The WTRU may transmit the distance metric feedback in a second UCI. The WTRU may transmit CSI feedback via UCI and distance metric(s) feedback via PUSCH. The WTRU may transmit distance metric feedback associated with multiple CSI feedback in a (e.g., single) UL PUSCH. The PUSCH resource may be a semi-persistent resource. The WTRU may transmit distance metric feedback in a MAC CE. The WTRU may be configured with a time and/or frequency relationship between CSI feedback and distance metric feedback. The WTRU may (e.g., explicitly or implicitly) indicate the relationship between the CSI feedback and the distance metric(s) feedback.

The WTRU may determine the number of distance metric(s) (e.g., k) to transmit. The WTRU may determine the number of distance metric(s) based on different parameters, as described herein. The WTRU may (e.g., explicitly or implicitly) indicate the number of distance metric(s) (e.g., k) included in the distance metric feedback. The WTRU may indicate, for a distance metric (e.g., each distance metric), the reference vector with which the distance metric is associated. For example, the WTRU may indicate a logical identity of a reference vector for a distance metric (e.g., for each distance metric). Such logical identity may be preconfigured for the WTRU.

The WTRU may be configured to report a minimum number of distance metrics (e.g., kₘᵢₙ) and a maximum number of distance metrics (e.g., Kₘₐₓ). The WTRU may then dynamically select the number of distance metrics k_{actual} based on one or more criteria, as described herein. The WTRU may indicate the k_{actual} number of distance metrics included in the distance metric feedback. The WTRU may indicate the number of additional distance metrics (e.g., k_{actual}−kₘᵢₙ) included in the distance metric feedback. The WTRU may indicate (e.g., only) the recommended number of distance metrics in the distance metric feedback. The WTRU may indicate the number of distance metric included in the distance metric feedback, the actual distances, and the associated reference vector identity.

The WTRU may be configured to quantize the distance metric indicated in the distance metric feedback. For example, the WTRU may be configured to apply quantization to the distance metrics based on preconfigured quantization parameters and transmit quantized distances. For example, the WTRU may apply scalar or vector quantization for distance metrics. For example, the WTRU may apply uniform or non-uniform quantization for distance metrics. The quantization parameters may be configured by the network. One or more quantization parameters may be determined (e.g., dynamically) by the WTRU. The WTRU may determine the quantization parameter based on a trade-off between accuracy and overhead. For example, given the configured feedback resource (e.g., PUSCH, PUCCH or the like) the WTRU may be configured to quantize the distance metric such that the accuracy of CSI reconstruction is maximized. For example, the WTRU may apply different quantization profiles based on the feedback resource (e.g., PUSCH or PUCCH). For example, the WTRU may apply different quantization levels for different distance metrics (e.g., as a function of importance of the distance metric). The WTRU may indicate the quantization parameters in the distance metric feedback. The WTRU may be preconfigured with a number of quantization profiles. A quantization profile (e.g., each quantization profile) may include quantization configurations applicable for quantizing distance metric. For example, a quantization profile (e.g., each quantization profile) may be associated with a logical ID. The WTRU may select a quantization profile (e.g., one of the quantization profiles) and apply the quantization profile to the distance metric (e.g., all the distance metrics) in the distance metric feedback. The WTRU may select different quantization profile specific to a distance metric (e.g., each distance metric). For example, the WTRU may quantize the distance metric with highest projection value with the largest number of bits. The WTRU may be configured to indicate the quantization profile(s) applied to the distance metric(s) by including the logical ID of quantization profile in the distance metric feedback.

A WTRU may determine the number of distances and/or metrics to report.

A WTRU may determine and report the number (k) of reference vectors for which to report distance metrics (e.g., as a function of a configured error threshold).

A WTRU in a system using two-sided models (e.g., AI/ML models) for CSI feedback may be configured to perform distance measurements (e.g., in support of compression performance determination by the NW-side). The configuration may include: a distance metric type to be used; a set of reference vectors; an input data type; and/or an error threshold percentage Thrₑᵣᵣ for the reconstruction performance calculation.

The WTRU may receive CSI-RS. The WTRU may determine measured CSI based on a measurement associated with the CSI-RS. The WTRU may calculate the compressed CSI from the measured CSI (e.g., based on the configured input data type (full H or EV)). The WTRU may determine how many distance metrics (k) to report (e.g., as a function of the configured error threshold). The WTRU may calculate Kₘₐₓ distances between the measured CSI and the configured set of reference vectors. The WTRU may determine the minimum number of distance metrics k, such that the energy of the distance metrics (e.g., projections) to the k reference vectors is larger than (100−Thrₑᵣᵣ)% of the total energy (e.g., the reported distance metrics conserve (100−Thrₑᵣᵣ)% of the energy).

The WTRU may report one or more of the following to the NW: the compressed CSI; the recommended number of distance metrics, k; the value of the k distance metrics; and/or an indication (e.g., index) of the associated reference vectors.

The network may configure the WTRU to report the recommended distance metrics, k.

A device (e.g., a wireless transmit/receive unit (WTRU)) may receive configuration information. The configuration information may indicate an input data type, a set of reference vectors (e.g., a first plurality of reference vector sets), a distance metric type, and an error threshold. The device may receive a channel state information (CSI) reference signal (CSI-RS). The device may determine measured CSI based on a measurement associated with the CSI-RS. The device may generate compressed CSI based on the measured CSI and the input data type. The device may determine a number of distances to report (e.g., based on the error threshold). The device may send a report to a network node. The report may include the compressed CSI and the number of distances.

The configuration information may further indicate a set of reference vectors. The device may calculate a plurality of distances, wherein the plurality of distances comprises distances between the measured CSI and each reference vector of the set of reference vectors. The device may determine a minimum number of distances, from the plurality of distances, for which an energy amount associated with the distances is greater than a threshold percentage of a total energy amount. The threshold percentage may be equal to one hundred minus the error threshold. The input data type may be a full channel matrix or an eigenvector.

The WTRU may determine the set of reference vectors and/or distances/metrics (e.g., the best distances/metrics) to report.

Example configuration aspects are provided herein.

The WTRU may receive a first plurality of reference vector sets. For example, the gNB may identify M1 different sets of reference vectors,

$$\{ {R}_{1}^{m} , {R}_{2}^{m} , … , {R}_{i}^{m} , … , {R}_{{K}_{max}}^{m} \} , m ∈ \{ 1 … M 1 \} .$$

The reference vectors across different sets may (e.g., may all) be different or partially overlapping (e.g., with a few common vectors). The reference vectors across different sets may (e.g., may all) be the same (e.g., but with a different ordering or priority associated with each of the underlying vectors).

The gNB may configure the WTRU with the M1 different sets.

The WTRU may determine a second plurality of reference vector sets based on the measured CSI. For example, the WTRU may (e.g., independently, or after observing the M1 sets from the gNB) identify M2 (e.g., additional) sets of reference vectors,

$$\{ {R}_{1}^{m} , {R}_{2}^{m} , … , {R}_{i}^{m} , … , {R}_{{K}_{max}}^{m} \} , m ∈ \{ 1 … M 2 \} .$$

The WTRU may determine that the M2 (e.g., additional) sets of reference vectors are more suited for distance-based detection.

The WTRU may indicate the M2 different sets to the gNB. For example, both the WTRU and gNB may have access to the M1+M2 sets.

The gNB may signal the parameter k, to the WTRU (e.g., to indicate how many distances for the WTRU to initially report). The gNB may configure the WTRU with an error threshold percentage Thrₑᵣᵣ for the reconstruction performance calculation (e.g., instead of defining the exact number of distances to be reported).

The WTRU may be configured (e.g., may receive configuration information) via RRC signaling or via control channel.

The WTRU may determine/select a set of reference vectors.

For a set (e.g., each of the M1+M2 sets), the WTRU may evaluate the Kₘₐₓ distances, as described herein.

The WTRU may select, based on the distance metric type, a reference vector set, from a combined set of reference vector sets (e.g., where the combined set of reference vector sets includes the first plurality of reference vector sets and the second plurality of reference vector sets). For example, if the WTRU is configured with k, (e.g., distances to be reported), the WTRU may (e.g., jointly) evaluate the best set (out of the M1+M2 sets) and the best k distances to report from the best set.

The “best distance” may depend on the distance metric being used. For example, the distance metric type may be a projection metric. If projection is being used as the distance metric, the best reference vectors may be determined based on the projection of the CSI onto the normalized reference vectors that is the largest. For example, the WTRU may select the reference vector set for which the projection of the measured CSI onto normalized reference vectors in the reference vector set is largest. If the MSE or L2-norm is the distance metric being used, the reference vectors with the smallest magnitude of the distances maybe more useful (e.g., may be considered the best distances). For example, the WTRU may select the reference vector set associated with a smallest mean squared error between the measured CSI and reference vectors in the reference vector set. The distances corresponding to the k best reference vectors may be the best k distances.

The set (e.g., in which the best k distances are overall most representative of the input CSI) may be utilized for the reporting. The WTRU may select the reference vector set that conserves a greatest total energy. For example, in the case of projection as the distance metric of choice, the set where the best k reference vectors represent the majority of the total energy of the input CSI (e.g., normalized sum of the projections, if the reference vectors are orthogonal) may be the best set for distance reporting.

The configuration information may indicate an error threshold percentage. The error threshold percentage may be in the range between 0 and 100 percent (e.g., with 0 percent indicating no error). The WTRU may select, based on the error threshold percentage, one or more reference vectors from the selected reference vector set. In this case, the report may indicate the selected one or more reference vectors. For example, if the WTRU is configured with Thrₑᵣᵣ (e.g., error threshold percentage), the WTRU may evaluate the best set (e.g., out of the M1+M2 sets), the value of k, and the best k distances to report from the best set.

For a set (e.g., each of the M1+M2 sets), the WTRU may determine the minimum number of distances k^{m}, such that the energy of the distances (e.g., projections) to the k^{m} reference vectors is larger than (100−Thrₑᵣᵣ)% of the total energy (e.g., the selected distances conserve (100−Thrₑᵣᵣ)% of the energy).

The m-th set with the smallest value of k^{m}, may be selected as the best set for distance-based reporting. The corresponding k^{m} distances may be the best distances (e.g., k=k^{m}).

The WTRU may (e.g., dynamically) activate and/or deactivate the set(s) of reference vectors. For example, the WTRU may activate a configured set of reference vectors if the WTRU receives an activation notification from the NW. As another example, the WTRU may deactivate a previously configured reference set, if the WTRU receives the notification for activating a new set.

The WTRU may send a report to a network node. The WTRU may report the determined set of reference vectors. For example, the report may indicate the compressed CSI and at least a part of the selected reference vector set.

The WTRU may report the identity of the selected set (e.g., out of the available M1+M2 sets). The sets may be represented as look-up-table (LUT) or codebook (e.g., because the sets are known at both the WTRU and the gNB). The index (e.g., only the index) associated with the selected set may be reported by the WTRU.

If the WTRU is configured with Thrₑᵣᵣ, the WTRU may report the value of k, indicating how many distances will be reported.

The WTRU may report the identity of the best k reference vectors (e.g., which are used for the distance measurements).

The WTRU may report the individual distances associated with the k reference vectors.

The choice and the quantity of the M2 sets specified by the WTRU may change with time. The WTRU may (e.g., dynamically and/or aperiodically) update the reference vectors in any of the M2 sets, or may introduce new sets of reference vectors.

The WTRU may determine the set of reference vectors and/or distances (e.g., best distances) and/or metrics to report.

A WTRU may select a set of reference vectors for which to determine and report distances (e.g., between measured CSI and the selected set of reference vectors). The WTRU may determine k distances (e.g., the best k distances) to report (e.g., based on channel conditions and/or pre-configured reporting parameters).

A WTRU in a system using two-sided models (e.g., AI/ML models) for CSI feedback may be configured to perform distance measurements. The network-side may use the distance measurements to determine compression performance. The configuration may include: a distance metric type to be used; an input data type; a number (M1) of sets of reference vectors. For example, a set of reference vectors may have different reference vectors from other sets of reference vectors. A set of reference vectors may have the same reference vectors as another set of reference vectors, but with a different ordering.

The WTRU may receive CSI-RS. The WTRU may measure the CSI-RS to determine measured CSI. The WTRU may determine additional (M2) sets of reference vectors (e.g., based on the measured CSI). The WTRU may indicate to the network the additional M2 sets of reference vectors. The WTRU may calculate the compressed CSI from the measured CSI (e.g., based on the configured input data type (full channel (H) or EV)).

For each set of reference vectors, the WTRU may determine the best k reference vectors to use. For example, the WTRU may select the vectors corresponding to the k smallest distances (or the k largest projections).

The WTRU may determine which set of reference vectors (e.g., out of the configured M1 and additional M2 sets of reference vectors) to use (e.g., as a function of the reporting configuration). For example, if the WTRU is configured to report k distances, the WTRU may select the reference set with smallest distances corresponding to the best k reference vectors in the set. If the WTRU is configured with an error threshold percentage Thrₑᵣᵣ for the reconstruction performance, the WTRU may select the reference set that conserves the most energy (e.g., the highest total energy for all the reference vectors in the reference set).

The WTRU may report one or more of the following: the compressed CSI; the selected set of reference vectors; an indication (e.g., an index) of the determined best reference vectors (e.g., associated with each reported distance/metric); and/or the determined best k distances/metrics between the measured CSI and the reference vectors.

A device (e.g., a wireless transmit/receive unit (WTRU)) may receive configuration information. The configuration information may indicate an input data type, a first plurality of reference vectors sets, a distance metric, and an error threshold. The device may receive a channel state information (CSI) reference signal (CSI-RS). The device may perform measurements on the CSI-RS to determine measured CSI. The device may calculate compressed CSI based on the measured CSI and the input data type. The device may determine a second plurality of reference vector sets (e.g., based on the measured CSI). The device may select a reference vector set, from the first plurality of reference vector sets and the second plurality of reference vector sets (e.g., based on the distance metric). The device may send a report to a network node. The report may include the compressed CSI, the selected reference vector set.

The device may send an indication of the second plurality of reference vector sets to the network node. The device may determine, for each reference vector set in the first plurality of reference vector sets, a subset of reference vectors (e.g., based on the distance metric and distances associated with the subset of reference vectors). The report may include an indication of the subset of reference vectors and the distances associated with the subset of reference vectors. Selecting the reference vector set, from the first plurality of reference vector sets and the second plurality of reference vector sets, may involve the device selecting the reference vector set with the best distances associated with the subset of reference vectors.

The configuration information may indicate an error threshold percentage. Selecting the reference vector set, from the first plurality of reference vector sets and the second plurality of reference vector sets, may involve the device selecting (e.g., based on the error threshold percentage) the reference set which conserves the highest total energy for all the reference vectors in the reference set. The input data type may be a full channel matrix or an eigenvector.

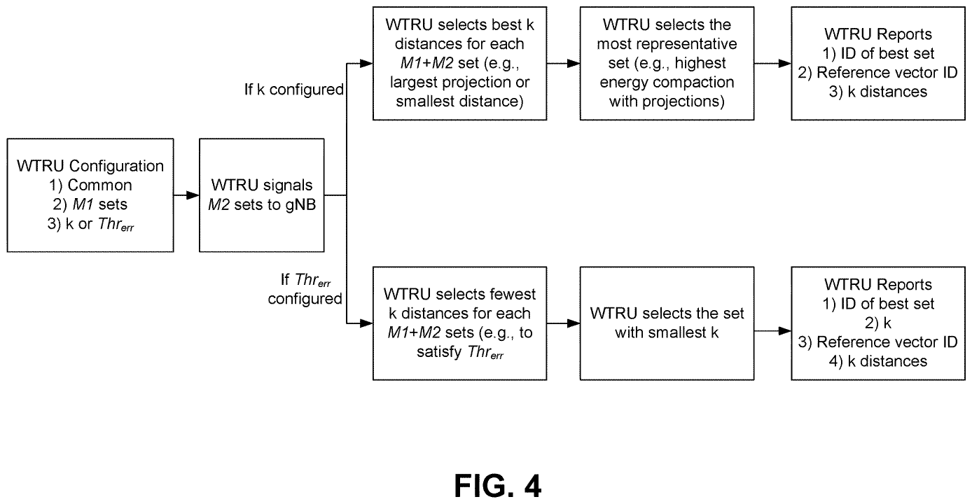

FIG. 4 illustrates an example of a WTRU determining the set of reference vectors.

The WTRU may (e.g., jointly) determine the distance/metrics reporting parameters.

Example configuration aspects are provided herein.

The WTRU may receive (e.g., from the gNB) configuration information associated with the maximum payload size B (e.g., which may be received over control channels, for example, PDCCH). The configuration may include an overhead threshold (e.g., the maximum overhead associated with WTRU's transmission for reporting the distances to the gNB). The WTRU may receive a distance metric type to be used, a set of reference vectors, an error threshold, a similarity threshold, a quantization threshold, and/or an input data type. Based on the configuration information, the WTRU may (e.g., jointly) determine the number of k distances to report, sub-band grouping and averaging, and/or quantization of each distance.

The WTRU may determine a distance measurement parameter.

The WTRU may measure and evaluate the distance. The WTRU may receive CSI-RS. The WTRU may determine measured CSI based on a measurement associated with the received CSI-RS. The WTRU may generate/calculate the compressed CSI based on the measured CSI and the input data type (e.g., full channel (FC) or eigenvectors (EV)).

For a sub-band (e.g., each of the sub-bands), the WTRU may estimate all Kₘₐₓ distances/distance metrics. The WTRU may decide which k<Kₘₐₓ distance metrics should be sent to satisfy the pre-defined error bound, Thrₑᵣᵣ. For example, if projection is used as a metric, the WTRU may determine the smallest k number of reference vectors such that the projection of the FC/EV on the k reference vectors conserves (100−Thrₑᵣᵣ)% of energy. The number of distances per sub-band may be impacted by the maximum payload size, B.

The WTRU may (e.g., after calculating the distances for each sub-band) determine sub-band groupings and a number of grouped sub-bands based on the similarity threshold (e.g., group the sub-bands by distances). The grouping metrics may be based on similarity (e.g., where groups of sub-bands having similar distances are considered redundant and that redundancy may be avoided). Distances may not be similar. Distances may be close (e.g., very close). The WTRU may define a similarity threshold Thrₛᵢₘ as the maximum difference between reference distances (e.g., that may disjoint two sets). If the difference is less than the threshold (e.g., Thrₛᵢₘ), the distances may be considered similar and the associated sub-bands may be grouped in the same sub-band group. For example, the WTRU may determine the first distance metric between the first reference vector and the measured CSI. The WTRU may determine the second distance metric between the second reference vector and the measured CSI. The WTRU may determine a difference between the first distance metric and the second distance metric. On a condition that the difference is less than the similarity threshold, the WTRU may group a sub-band associated with the first distance metric and a sub-band associated with the second distance metric in a sub-band group.

The WTRU may (e.g., after grouping) optimize (e.g., jointly optimize) the overhead (e.g., instead of reporting the original values of distances). The WTRU may compute the average value related to each group. Other moments may be employed to distinguish groups (e.g., each group). Contributing weights may be calculated for a distance (e.g., each of the k distances). For example, the sum of weights may be equal to 1. The sub-band grouping may be impacted by the bit budget B.

The WTRU may quantize k distances for each of the sub-band groups. The WTRU may determine a quantization level (e.g., based on the quantization threshold). The quantization may depend on the bit budget constraint. The WTRU may use a uniform quantization function for each distance, or a mixture of uniform and non-uniform quantization functions. The quantization function may be dynamic and data-driven (e.g., aiming to minimize the quantization error). The number of quantization bits used for a distance (e.g., each distance) may be impacted by the maximum payload size B. If more quantization levels are employed, the overhead and/or the accuracy of the detection of the compression performance may increase. Similarly, if less quantization bits are employed for the distances, the accuracy of the detection of the compression performance may decrease. The WTRU may use a threshold for quantization error Thr_{q} to meet the maximum payload size B with an acceptable quantization error.

The WTRU may determine the number of distances (k) to report, the quantization for the reported distances, and/or the sub-band averaging, for a configured report payload B (e.g., bit budget B).

The WTRU may determine k<Kₘₐₓ distances that satisfy the pre-defined error bound Thrₑᵣᵣ.

The WTRU may determine sub-band groupings. The WTRU may determine the number of grouped sub-bands N_{G} that satisfy the similarity threshold Thrₛᵢₘ.

The quantization level may indicate a number of bits used to represent a scalar distance value between the measured CSI and a reference vector in the set of reference vectors. The WTRU may determine the quantization level, Q, (e.g., the number of bits used to represent a scalar distance value) that satisfies the quantization error threshold, Thr_{q}. The WTRU may report one or more distance metrics, from the set of distance metrics, in accordance with the number of bits.

The WTRU may determine a total payload size based on the number of distances, the number of grouped sub-bands, and the quantization level. For example, the WTRU may compute the total payload size (e.g., by Nₚ=k·N_{G}·Q).

If Nₚ≤B, the WTRU may use k distances for N_{G} subgroups and quantization level Q.

If Nₚ>B, the WTRU may change the threshold values (e.g., so that Thrₑᵣᵣ=Thrₑᵣᵣ+Δₑ, Thrₛᵢₘ=Thrₛᵢₘ+Δₛ, and Thr_{q}=Thr_{q}+Δ_{q}). The WTRU may then (re-)determine k<Kₘₐₓ distances that satisfy the pre-defined error bound Thrₑᵣᵣ.

The WTRU may transmit k distances per sub-band groups with the determined quantization level.

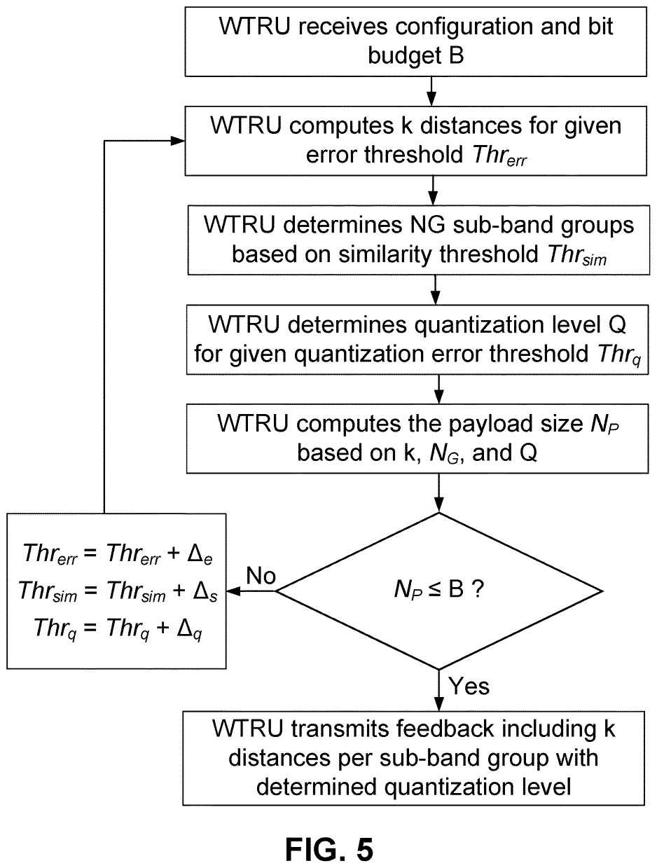

FIG. 5 illustrates an example of (e.g., jointly) determining the number of distances (k) to report, the quantization for the reported distances, and the sub-band averaging (e.g., grouping), for a configured report payload B.

The WTRU may report distance measurement parameters.

The WTRU may report the distance measurement parameters to the gNB using control channels (e.g., PUCCH). The reported parameters may include one or more of the following: the parameter k, the k calculated distances; sub-band grouping identification (e.g., a set of indexes and sub-bands that belong to each index); an average distance in each group (e.g., or other moments); a number of quantization bits used for a distance in a sub-band (e.g., each distance in each sub-band), and/or the like. If the quantization is non-uniform, a field may be reserved to report the quantization parameters separately.

A WTRU may determine (e.g., jointly determine) the distances/distance metrics, and/or reporting parameters.

A WTRU may determine (e.g., jointly determine) a number (k) of distances (between a measured CSI and a reference vector) to report per subband, a group of subbands, and/or distance measurement quantization (e.g., based on the feedback report payload).

A WTRU in a system using two-sided models (e.g., AI/ML models) for CSI feedback may be configured to perform distance measurements (e.g., to be used by the NW-side to determine compression performance). The configuration may include one or more of the following: a distance metric type to be used; a set of reference vectors; an input data type; and/or a maximum overhead (B number of bits) associated with the reporting of the distance metrics.

The WTRU may receive CSI-RS. The WTRU may determine measured CSI based on measurements on the CSI-RS. The WTRU may calculate the compressed CSI from the measured CSI (e.g., based on the configured input data type (full H or EV)). The WTRU may determine (e.g., jointly determine) the number of distances (k) to report, the quantization for the reported distances, and/or the sub-band averaging (e.g., as a function of the configured report payload, B).

The WTRU may calculate Kₘₐₓ distances for an allocated sub-band (e.g., each allocated sub-band). The WTRU may determine which k distances to report for each sub-band (e.g., to satisfy the configured error threshold).

The WTRU may determine the grouping of the sub-bands for averaging. The WTRU may determine the quantization of a distance (e.g., each of the k distances) per sub-band.

The WTRU may report one or more of the following: the determined sub-band grouping for averaging; the measured k distances and the index of the corresponding reference vectors; and/or quantization information for the reported distances.

A device (e.g., a wireless transmit/receive unit (WTRU)) may receive configuration information. The configuration information may indicate an input data type, a set of reference vectors, a distance metric type, an error threshold, a similarity threshold, a quantization threshold, and an overhead threshold. The device may receive a channel state information (CSI) reference signal (CSI-RS). The device may determine measured CSI based on a measurement associated with the CSI-RS. The device may generate compressed CSI based on the measured CSI and the input data type.

The device may determine a number of distances based on the error threshold. For example, the device may determine a set of distance metrics based on the distance metric type. The set size of the set of distance metrics may be indicative of a number of distance metrics in the set of distance metrics. The set of distance metrics may include a first distance metric associated with the measured CSI and a first reference vector in the set of reference vectors, and a second distance metric associated with the measured CSI and a second reference vector in the set of reference vectors. The device may determine, based on the error threshold, a quantity of the number of distance metrics to report.

The device may determine sub-band groupings and a number of grouped sub-bands based on the similarity threshold. The device may determine a quantization level based on the quantization threshold. The device may compute a total payload size based on the number of distances, the number of grouped sub-bands, and the quantization level. The device may send a report to a network node. The report may indicate the compressed CSI.

On a condition that the total payload size is less than or equal to the overhead threshold, the report may indicate the quantity of the number of distance metrics, the number of grouped sub-bands, and the quantization level. The input data type may be a full channel matrix or an eigenvector.

The error threshold may be a first error threshold. The similarity threshold may be a first similarity threshold. The quantization threshold may be a first quantization threshold. On a condition that the total payload size is greater than the overhead threshold, the device may increment the first error threshold to obtain a second error threshold; increment the first similarity threshold to obtain a second similarity threshold; increment the first quantization threshold to obtain a second quantization threshold; determine a second quantity of the number of distance metrics based on the second error threshold; determine second sub-band groupings and a second number of grouped sub-bands based on the second similarity threshold; determine a second quantization level based on the second quantization threshold; and compute a second total payload size based on the second number of distance metrics, the second number of grouped sub-bands, and the second quantization level. The report may indicate the second quantity of the number of distance metrics, the second number of grouped sub-bands, and the second quantization level.

Although features and elements described above are described in particular combinations, each feature or element may be used alone without the other features and elements of the preferred embodiments, or in various combinations with or without other features and elements.

Although the implementations described herein may consider 3GPP specific protocols, it is understood that the implementations described herein are not restricted to this scenario and may be applicable to other wireless systems. For example, although the solutions described herein consider LTE, LTE-A, New Radio (NR) or 5G specific protocols, it is understood that the solutions described herein are not restricted to this scenario and are applicable to other wireless systems as well. For example, while the system has been described with reference to a 3GPP, 5G, and/or NR network layer, the envisioned embodiments extend beyond implementations using a particular network layer technology. Likewise, the potential implementations extend to all types of service layer architectures, systems, and embodiments. The techniques described herein may be applied independently and/or used in combination with other resource configuration techniques.

The processes described herein may be implemented in a computer program, software, and/or firmware incorporated in a computer-readable medium for execution by a computer and/or processor. Examples of computer-readable media include, but are not limited to, electronic signals (transmitted over wired and/or wireless connections) and/or computer-readable storage media. Examples of computer-readable storage media include, but are not limited to, a read only memory (ROM), a random access memory (RAM), a register, cache memory, semiconductor memory devices, magnetic media such as, but not limited to, internal hard disks and removable disks, magneto-optical media, and/or optical media such as compact disc (CD)-ROM disks, and/or digital versatile disks (DVDs). A processor in association with software may be used to implement a radio frequency transceiver for use in a WTRU, terminal, base station, RNC, and/or any host computer.

It is understood that the entities performing the processes described herein may be logical entities that may be implemented in the form of software (e.g., computer-executable instructions) stored in a memory of, and executing on a processor of, a mobile device, network node or computer system. That is, the processes may be implemented in the form of software (e.g., computer-executable instructions) stored in a memory of a mobile device and/or network node, such as the node or computer system, which computer executable instructions, when executed by a processor of the node, perform the processes discussed. It is also understood that any transmitting and receiving processes illustrated in figures may be performed by communication circuitry of the node under control of the processor of the node and the computer-executable instructions (e.g., software) that it executes.

The various techniques described herein may be implemented in connection with hardware or software or, where appropriate, with a combination of both. Thus, the implementations and apparatus of the subject matter described herein, or certain aspects or portions thereof, may take the form of program code (e.g., instructions) embodied in tangible media including any other machine-readable storage medium wherein, when the program code is loaded into and executed by a machine, such as a computer, the machine becomes an apparatus for practicing the subject matter described herein. In the case where program code is stored on media, it may be the case that the program code in question is stored on one or more media that collectively perform the actions in question, which is to say that the one or more media taken together contain code to perform the actions, but that—in the case where there is more than one single medium—there is no requirement that any particular part of the code be stored on any particular medium. In the case of program code execution on programmable devices, the computing device generally includes a processor, a storage medium readable by the processor (including volatile and non-volatile memory and/or storage elements), at least one input device, and at least one output device. One or more programs that may implement or utilize the processes described in connection with the subject matter described herein, e.g., through the use of an API, reusable controls, or the like. Such programs are preferably implemented in a high level procedural or object oriented programming language to communicate with a computer system. However, the program(s) can be implemented in assembly or machine language, if desired. In any case, the language may be a compiled or interpreted language, and combined with hardware implementations.

Although example embodiments may refer to utilizing aspects of the subject matter described herein in the context of one or more stand-alone computing systems, the subject matter described herein is not so limited, but rather may be implemented in connection with any computing environment, such as a network or distributed computing environment. Still further, aspects of the subject matter described herein may be implemented in or across a plurality of processing chips or devices, and storage may similarly be affected across a plurality of devices. Such devices might include personal computers, network servers, handheld devices, supercomputers, or computers integrated into other systems such as automobiles and airplanes.

In describing preferred embodiments of the subject matter of the present disclosure, as illustrated in the Figures, specific terminology is employed for the sake of clarity. The claimed subject matter, however, is not intended to be limited to the specific terminology so selected, and it is to be understood that each specific element includes all technical equivalents that operate in a similar manner to accomplish a similar purpose.

1. A wireless transmit/receive unit (WTRU) comprising:
a processor configured to:
receive configuration information, wherein the configuration information indicates an input data type, a set of reference vectors, and a distance metric type;
receive a channel state information (CSI) reference signal (CSI-RS);
determine measured CSI based on a measurement associated with the CSI-RS;
generate compressed CSI based on the measured CSI and the input data type;
calculate, based on the distance metric type, a distance metric associated with the measured CSI and a reference vector in the set of reference vectors; and
send a report to a network node, wherein the report indicates the compressed CSI and the distance metric associated with the measured CSI and the reference vector in the set of reference vectors.

2. The WTRU of claim 1, wherein the processor being configured to calculate the distance metric associated with the measured CSI and the reference vector in the set of reference vectors comprises the processor being configured to calculate respective distance metrics between the measured CSI and each reference vector in the set of reference vectors.

3. The WTRU of claim 1, wherein the distance metric type is a normalized mean square error (NMSE), and the processor being configured to calculate the distance metric associated with the measured CSI and the reference vector in the set of reference vectors comprises the processor being configured to calculate the NMSE of the measured CSI and the reference vector in the set of reference vectors.

4. The WTRU of claim 1, wherein the distance metric type is a cosine similarity, and the processor being configured to calculate the distance metric associated with the measured CSI and the reference vector in the set of reference vectors comprises the processor being configured to calculate the cosine similarity of the measured CSI and the reference vector in the set of reference vectors.

5. The WTRU of claim 1, wherein the processor being configured to calculate the distance metric associated with the measured CSI and the reference vector in the set of reference vectors comprises the processor being configured to calculate respective distance metrics between the measured CSI and each reference vector in the set of reference vectors, and wherein the report further indicates a smallest distance metric of the respective distance metrics or a largest distance metric of the respective distance metrics.

6. The WTRU of claim 1, wherein the distance metric type comprises a function that maps input tensors to a scalar value, wherein the distance metric associated with the measured CSI and the reference vector in the set of reference vectors comprises the scalar value.

7. The WTRU of claim 1, wherein the reference vector is associated with a first domain, the distance metric type is associated with a second domain, and the processor is further configured to transform the reference vector from the first domain to the second domain.

8. The WTRU of claim 1, wherein the input data type comprises full channel matrix or eigenvector.

9. A method, to be performed by a wireless transmit/receive unit (WTRU), the method comprising:
receiving configuration information, wherein the configuration information indicates an input data type, a set of reference vectors, and a distance metric type;
receiving a channel state information (CSI) reference signal (CSI-RS);
determining measured CSI based on a measurement associated with the CSI-RS;
generating compressed CSI based on the measured CSI and the input data type;
calculating, based on the distance metric type, a distance metric associated with the measured CSI and a reference vector in the set of reference vectors; and
sending a report to a network node, wherein the report indicates the compressed CSI and the distance metric associated with the measured CSI and the reference vector in the set of reference vectors.

10. The method of claim 9, wherein calculating the distance metric associated with the measured CSI and the reference vector in the set of reference vectors comprises calculating respective distance metrics between the measured CSI and each reference vector in the set of reference vectors.

11. The method of claim 9, wherein the distance metric type is a normalized mean square error (NMSE), and calculating the distance metric associated with the measured CSI and the reference vector in the set of reference vectors comprises calculating the NMSE of the measured CSI and the reference vector in the set of reference vectors.

12. The method of claim 9, wherein the distance metric type is a cosine similarity, and calculating the distance metric associated with the measured CSI and the reference vector in the set of reference vectors comprises calculating the cosine similarity of the measured CSI and the reference vector in the set of reference vectors.

13. The method of claim 9, wherein calculating the distance metric associated with the measured CSI and the reference vector in the set of reference vectors comprises calculating respective distance metrics between the measured CSI and each reference vector in the set of reference vectors, and wherein the report further indicates a smallest distance metric of the respective distance metrics or a largest distance metric of the respective distance metrics.

14. The method of claim 9, wherein the distance metric type comprises a function that maps input tensors to a scalar value, wherein the distance metric associated with the measured CSI and the reference vector in the set of reference vectors comprises the scalar value.

15. The method of claim 9, wherein the reference vector is associated with a first domain, the distance metric type is associated with a second domain, and the method further comprises transforming the reference vector from the first domain to the second domain.

16. The method of claim 9, wherein the input data type comprises full channel matrix or eigenvector.
